(19) United States
(12) Patent Application Publication
(10) Pub. No.: US 2018/0254077 A1
(43) Pub. Date: Sep. 6, 2018

(54) SELF-ALIGNED MEMORY ARRAY

(71) Applicant: Intel Corporation, Santa Clara, CA (US)

(72) Inventors: Elijah V. Karpov, Santa Clara, CA (US); Uday Shah, Portland, OR (US); Ravi Pillarisetty, Portland, OR (US); Brian S. Doyle, Portland, OR (US)

(21) Appl. No.: 15/755,566

(22) PCT Filed: Sep. 24, 2015
(86) PCT No.: PCT/US15/52051

§ 371 Date: Feb. 27, 2018

(51) Int. Cl. G11C 11/16; H01L 27/22; H01L 43/08; G11C 11/14

(52) U.S. Cl. CPC G11C 11/161; G11C 11/1659; G11C 11/14; H01L 43/08; H01L 27/226

(57) ABSTRACT

An embodiment includes a memory array comprising: a memory cell including a switch stack in series with a memory stack; and a bit line above the memory cell and a word line below the memory cell; wherein (a) first switch stack sidewalls of the switch stack are vertically aligned with bit line sidewalls of the bit line and second switch stack sidewalls of the switch stack are vertically aligned with word line sidewalls of the word line; (b) first memory stack sidewalls of the memory stack are vertically aligned with the bit line sidewalls and second memory stack sidewalls of the memory stack are vertically aligned with the word line sidewalls. Other embodiments are described herein.

### TECHNICAL FIELD

Embodiments of the invention are in the field of semiconductor devices and, in particular, memory.

### BACKGROUND

Some magnetic memories, such as a spin transfer torque magnetic random access memory (STT-MRAM), utilize a magnetic tunnel junction (MTJ) for switching and detection of the memory's magnetic state. A MTJ consists of ferromagnetic (FM) layers and a tunneling barrier (e.g., MgO). The MTJ couples a bit line (BL) to a selection switch (e.g., transistor), word line (WL), and sense line (SL). The MTJ memory is “read” by assessing the change of resistance (e.g., tunneling magnetoresistance (TMR)) for different relative magnetizations of the FM layers.

More specifically, in STT-MRAM each bit of data is stored in a separate MTJ. One of the FM layers is called the reference layer (RL), and it provides a stable reference magnetic orientation. The bit is stored in the second FM layer, which is called the free layer (FL), and the orientation of the magnetic moment of the free layer can be, for example, in either of two states: parallel to the reference layer or anti-parallel to the reference layer. Because of the TMR effect, the electrical resistance of the anti-parallel state is significantly higher compared to the parallel state.

To write information in a STT-MRAM device, the spin transfer torque (STT) effect is used to switch the free layer from the parallel to anti-parallel state and vice versa. The passing of current through the MTJ produces spin polarized current, which results in a torque being applied to the magnetization of the free layer. When the spin polarized current is sufficiently strong, enough torque is applied to the free layer to cause its magnetic orientation to change, thus allowing for bits to be written. To read the stored bit, the sensing circuitry measures the resistance of the MTJ.

### BRIEF DESCRIPTION OF THE DRAWINGS

Features and advantages of embodiments of the present invention will become apparent from the appended claims, the following detailed description of one or more example embodiments, and the corresponding figures. Where considered appropriate, reference labels have been repeated among the figures to indicate corresponding or analogous elements.

FIG. 1 includes a method of forming a memory in an embodiment of the invention;

FIGS. 2A-2C include stages of formation of an embodiment of the invention; and

FIG. 3 includes a system that may comprise embodiments of memory described herein.

### DETAILED DESCRIPTION

Reference will now be made to the drawings wherein like structures may be provided with like suffix reference designations. In order to show the structures of various embodiments more clearly, the drawings included herein are diagrammatic representations of semiconductor/circuit structures. Thus, the actual appearance of the fabricated integrated circuit structures, for example in a photomicrograph, may appear different while still incorporating the claimed structures of the illustrated embodiments. Moreover, the drawings may only show the structures useful to understand the illustrated embodiments. Additional structures known in the art may not have been included to maintain the clarity of the drawings. For example, not every layer of a semiconductor device is necessarily shown. “An embodiment”, “various embodiments” and the like indicate embodiment(s) so described may include particular features, structures, or characteristics, but not every embodiment necessarily includes the particular features, structures, or characteristics. Some embodiments may have some, all, or none of the features described for other embodiments. “First”, “second”, “third” and the like describe a common object and indicate different instances of like objects are being referred to. Such adjectives do not imply objects so described must be in a given sequence, either temporally, spatially, in ranking, or in any other manner. “Connected” may indicate elements are in direct physical or electrical contact with each other and “coupled” may indicate elements co-operate or interact with each other, but they may or may not be in direct physical or electrical contact.

As mentioned above, an MTJ typically couples a BL to a selection switch (e.g., transistor), WL, and SL. However, when many MTJs are formed in a memory array, the array size may undesirably grow due to the size of the selections switches in the array. The array size may grow to the extent that is less than ideal to serve as embedded memory in a system on a chip (SoC). For example, complementary metal-oxide semiconductor (CMOS) transistors can take up valuable real estate.

Embodiments address this space issue by using thin film switching elements instead of the CMOS transistor. As a result, a memory cell may include a thin film switching element in series with a memory element (e.g., MTJ). The switching element may couple to a WL while the memory element couples to a BL. Depending on row and column selector logic and sensing, one of the switching element and the memory element may couple to a SL and/or possibly another BL (e.g., one BL for reading that couples to one electrode of an MTJ and another BL for writing that couples to another electrode of an MTJ).

A thin film switching element that may be used includes, in an embodiment, one of the switching elements addressed in U.S. Patent Application Number 2014/0209892, assigned to Intel Corporation of Santa Clara, Calif., U.S.A. The application discloses a “selector with snapback.”

Specifically, in a selector without snapback once the voltage across a bit cell exceeds the threshold VTH, the selector without snapback transitions the bit cell from an OFF-state to an ON-state. However, the selector and memory write voltage cannot be accommodated at the given voltage supply VCELL (which is the maximum voltage that can be applied across the memory cell) because the ‘ON’ voltage of the selector exceeds VCELL. In contrast, in a selector with snapback once the voltage across a bit cell exceeds the threshold VTH, the selector with snapback transitions the bit cell from an OFF-state to an ON-state by changing from an insulator-like material to a metal-like conductive material, and as a result, snaps back to a hold voltage VH thereby accommodating the same memory under the same VCELL requirement. The selector is configured such that the selector turns off once the voltage across the bit cell falls below the hold voltage VH (or hold current, IH). The snapback voltage VSnapback equals the threshold voltage VTH minus the hold voltage VH. Said differently, the snapback voltage VSnapback is the voltage drop across the selector in the ON-state. The snapback of the selector is exploited to accommodate the ON-state voltage of the selector under the given maximum supply voltage VCELL, wherein without the snapback, the ON-state voltage would exceed that maximum supply voltage. In some example embodiments, the maximum supply voltage VCELL can be less than 1 volt (e.g., 0.9 volts or less).

An embodiment of a snapback selector includes an insulator material sandwiched between two electrode materials. The electrodes can be implemented with any number of suitable materials such as, but not limited to, carbon, gold, nickel, platinum, silver, molybdenum, molybdenum nitride, molybdenum carbide, titanium, titanium nitride, titanium carbide, tungsten, tungsten carbide, tungsten nitride, and mixtures thereof, as well as conductive metal oxides. The insulator may include crystalline materials that enable a selector with an S-shaped IV characteristic or otherwise exhibit a snapback condition. Such materials generally include, but are not limited to, multi-component oxide and alloy systems that contain metals from periods 4, 5, or 6 of the periodic table, and generally have partially filled valence d-shells. Ideally, such materials behave as an insulator (e.g., with only negligible leakage currents) in the OFF-state when biased below VTH, and act as a metal (e.g., which conducts high currents) at relatively low biases when switched to the ON-state. The transition is reversible: when the bias is removed or otherwise no longer satisfied, the material returns to its original insulating state.

In some specific example embodiments, the selector insulator is implemented with vanadium oxide (VO₂), manganese oxide (MnO), or titanium oxide (Ti₂O₃). Other so-called MOTT insulators having S-shaped IV curves with snapback may be used as well for the selector insulator, such as iron oxide (Fe₂O₃), niobium oxide (NbO₂), and tantalum oxide (TaO₂). In some embodiments, a mixture of such oxides can be used. In other embodiments, the insulator of the selector element can be implemented with oxides referred to as Perovskites having the chemical formula R₍₁₋ₓ₎AₓBO₃, where R is a rare-earth atom, A is a bivalent atom, and B may be selected from manganese, nickel, cobalt, titanium, or vanadium. In some embodiments, a mixture of such Perovskites can be used. In still other embodiments, the insulator of the selector element can be implemented with crystalline sulfides such as chromium sulphide (CrS) and iron sulphide (FeS), or a combination of such sulphides. In still other embodiments, the insulator of the selector element can be implemented with a combination of such crystalline oxides, Perovskites, and/or sulphides. Numerous variations will be apparent. Note that such crystalline materials with S-shaped IV characteristic are distinct from ovonic threshold switching chalcogenide materials with S-shaped IV characteristic which are amorphous. Each of these example materials generally exhibits a bidirectional S-shaped I-V characteristic or otherwise allow for a snapback condition and can be used to implement the insulator layer of a selector element in accordance with an embodiment of the present invention.

With such electrical characteristic and material systems in hand, the selector can be achieved with thin films in the backend semiconductor process, in accordance with some embodiments of the present invention. Building the embedded memory in the backend means that a dense cross point array cell can be achieved, example embodiments of which will be discussed in turn. For instance, a backend selector process enables the option of having multiple layers of selector plus memory elements on top of the logic periphery.

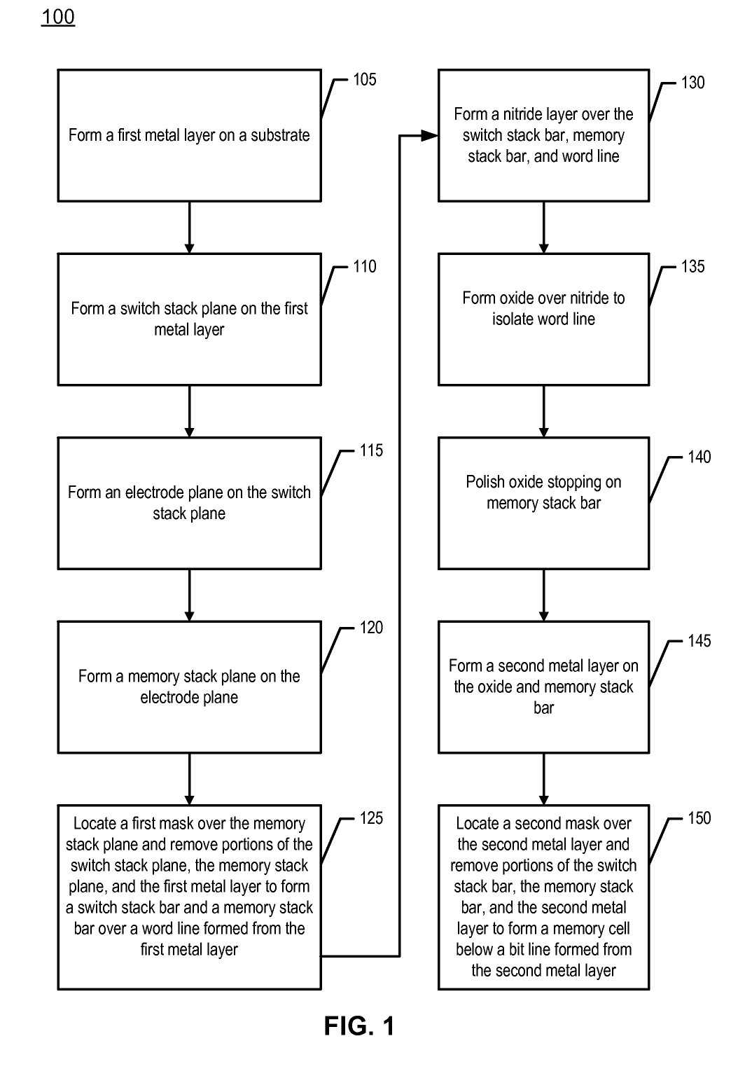

FIG. 1 includes a method 100 of forming a memory in an embodiment of the invention.

Method 100 includes forming a first metal layer on a substrate (block 105). Such a substrate may be a bulk semiconductive material that is part of a wafer. In an embodiment, the semiconductive substrate is a bulk semiconductive material as part of a chip that has been singulated from a wafer. In an embodiment, the semiconductive substrate is a semiconductive material that is formed above an insulator such as a semiconductor on insulator (SOI) substrate. In an embodiment, the semiconductive substrate is a prominent structure such as a fin that extends above a bulk semiconductive material.

Next a switch stack plane is formed on the first metal layer (block 110).

As used herein terms, such as left, right, top, bottom, over, under, upper, lower, first, second are used for descriptive purposes only and are not to be construed as limiting. For example, terms designating relative vertical position refer to a situation where a device side (or active surface) of a substrate or integrated circuit is the “top” surface of that substrate; the substrate may actually be in any orientation so that a “top” side of a substrate may be lower than the “bottom” side in a standard terrestrial frame of reference and still fall within the meaning of the term “top.” The term “on” as used herein (including in the claims) does not indicate that a first layer “on” a second layer is directly on and in immediate contact with the second layer unless such is specifically stated; there may be a third layer or other structure between the first layer and the second layer on the first layer.

With this in mind, the switch back stack plane may be one or more insulative/via layers and/or metal layers above the first metal layer (and the first metal layer may be one or more layers above the substrate). The switch back stack plane may extend as broadly as the first metal layer. The switch back stack is a “stack” because it includes a stack of layers, such as a lower electrode layer, an insulator, and an upper electrode layer. The insulator layer may directly contact the lower and upper electrode layers. A layer as used herein may itself include sublayers. Thus, a lower electrode layer may have sublayers. At this point in the process, the WL has not been formed from the first metal layer and the switch back stack plane is wider in the horizontal dimension than the eventual switch stack switching element in the final memory cell, and is therefore called a “bar” because it looks like a bar.

Next, an electrode plane is formed on the switch stack plane (e.g., block 115). The electrode plane may be a metal layer or layers. These layers may serve as a barrier to stop diffusion between the eventual thin film switching element and the memory element. However, in some embodiment no such barrier is required so the electrode or barrier plane may be omitted.

Next a memory stack plane is formed on the electrode plane (if the electrode plane is included in the embodiment) and/or the switch stack selector plane (block 120). The memory stack is a “stack” because, in examples where the eventual memory unit is a MTJ, the stack includes a stack of layers such as a lower electrode layer, a tunnel oxide/insulator, and an upper electrode layer. The insulator layer may directly contact the lower and upper electrode layers. At this point in the process, the WL has not been formed from the first metal layer and the memory stack plane is wider in the horizontal dimension than the eventual memory element in the final memory cell.

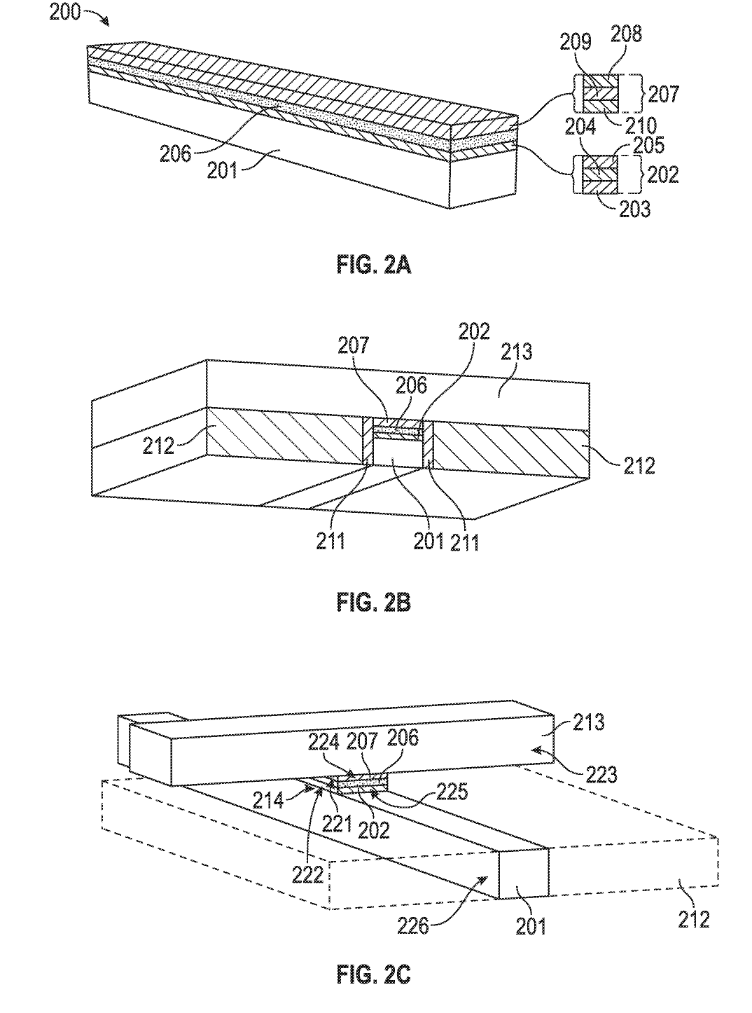

Next the method includes locating a first mask over the memory stack plane and removing portions of the switch stack plane, the memory stack plane, and the first metal layer to form a switch stack bar and a memory stack bar over a word line formed from the first metal layer (block 125). Doing so yields the “bars” seen in FIG. 2A.

FIG. 2A includes WL 201, switch stack bar 202 (including lower electrode layer 203, insulative layer 204, and upper electrode layer 205), electrode layer 206, and memory stack 207 (including lower electrode layer 210, tunnel oxide/insulative layer 209 (when an MTJ is the memory element), and upper electrode layer 208).

Returning to FIG. 1, next process 100 includes forming a nitride layer over the switch stack bar, memory stack bar, and word line (block 130). The nitride is optional but may be used to prevent oxidation of materials like the metal (e.g., Cu) included in the WL layer. Block 135 includes forming oxide (e.g., SiO₂) over the nitride to isolate the WL and then, in block 140, planarizing (e.g., chemical mechanical planarization (CMP)) the oxide stopping on the memory stack bar.

Block 145 includes forming a second metal layer 213 on the oxide 212 and memory stack bar 207. This yields the embodiment shown in FIG. 2B, which includes nitride 211 and dielectric/oxide 212.

Block 150 includes locating a second mask over the second metal layer 213 and removing portions of the switch stack bar 202, the memory stack bar 207, electrode layer 206, and the second metal layer 213 to form a memory cell 214 below a BL 213 formed from the second metal layer. This yields the embodiment shown in FIG. 2C.

Afterwards, nitride may again encapsulate (not shown) exposed elements and layers like cell 214 and BL 213. Oxide may then be added to insulate the cell and the BL (not shown).

The above procedure may be performed en masse to produce an array. In an embodiment, the array may include various features now described with references to FIGS. 2A-2C.

An embodiment includes a memory array that comprises many memory cells, such as memory cell 214. Cell 214 includes a switch stack in series with a memory stack. In various embodiments the switch stack may be closer to the WL and the memory stack may be closer to the BL but in other embodiments the switch stack may be closer to the BL and the memory stack may be closer to the WL.

In an embodiment the switch stack 202 may include an insulator 204 below an upper electrode 205 and above a lower electrode 203. In an embodiment the insulator includes at least one of vanadium oxide, manganese oxide, titanium oxide, iron oxide, niobium oxide, tantalum oxide, chromium sulphide, iron sulphide, and a compound having the chemical formula R₍₁₋ₓ₎AₓBO₃, where R is a rare-earth atom, A is a bivalent atom, and B may be selected from manganese, nickel, cobalt, titanium, or vanadium.

In an embodiment the memory stack 207 may include a MTJ having a tunnel oxide 209 between electrodes 207, 208. However, in other embodiments memory stack 207 may include, for example and without limitation, resistive random access memory (RRAM or ReRAM). RRAM relies on a class of materials that switch in a one-time event from a virgin insulating state to a low resistive state by way of a “forming” event. In the forming event, the device goes through “soft breakdown” in which a localized filament forms in a dielectric layer located between two electrodes. This filament shunts current through the filament to form a low resistance state. The RRAM switches from a low to a high resistive state (by disbanding the filament) and from a high to a low resistive state (by reforming the filament) by applying voltages of different polarities to the electrodes to switch the state. The filament may include oxygen vacancies, metal particles (conductive bridge RAM (CBRAM)), and the like depending on the type of RRAM used. Embodiments broadly include resistive switching memories, which include, without limitation, oxide vacancy filament RRAM, conductive bridging RAM (CBRAM), phase change memory (PCM) RAM, and interfacial switching RRAM. Such examples of RRAM have a thermal component to be managed. Not all RRAM require forming events and embodiments include such RRAMs.

The embodiment may include BL 213 above the memory cell 214 and WL 201 below the memory cell. The switch stack includes first sidewalls, one of which is labeled 225 and the other of which (opposite to wall 225) is obscured from sight by cell 214. The switch stack sidewalls, such as wall 225, are vertically aligned with sidewalls of the BL bit line, one of which is labeled 223 and the other of which (opposite to wall 223) is obscured from cite by BL 213. Second switch stack sidewalls (one of which is labeled 222 and the other of which (opposite to wall 222) is obscured from sight by cell 214) are vertically aligned with sidewalls of WL 201 (one of which is labeled 226 and the other of which (opposite to wall 226) is obscured from sight by WL 201. Further, memory stack sidewalls (one of which is labeled 224 and the other of which (opposite to wall 224) is obscured from sight by cell 214) are vertically aligned with the bit line sidewalls (one of which is wall 223) and memory stack sidewalls (one of which is labeled 221 and the other of which (opposite to wall 221) is obscured from sight by cell 214) are vertically aligned with the word line sidewalls 226 (and the sidewall opposite wall 226).

In the embodiment of FIG. 2C, sidewalls 222, 225 are orthogonal to each other and sidewalls 221, 224 are orthogonal to each other.

Block 125 of FIG. 1 describes how sidewalls 224, 225 are “self-aligned” to WL 201, and more specifically sidewall 226. Block 150 of FIG. 1 describes how sidewalls 221, 222 are “self-aligned” to BL 213, and more specifically sidewall 223. Put another way, a single etch may remove portions the switch stack, memory stack, and metal layer 201 all based on a single mask thereby resulting in the sidewalls of those elements be aligned to each other and the patterns of the mask. Then a single etch may remove portions the switch stack, memory stack, and metal layer 213 all based on a single mask thereby resulting in the sidewalls of those elements be aligned to each other and the patterns of the mask.

In an embodiment switch stack sidewalls 222, 225 are included in a selector element having a threshold voltage VTH, an ON-state voltage, and a snapback voltage VSnapback, such that the selector element transitions from an OFF-state to an ON-state when a voltage potential across the selector element exceeds VTH, and the selector element snaps back to a hold voltage VH while maintaining the ON-State. Without the snapback voltage VSnapback, the ON-state voltage would exceed a maximum voltage potential that can be applied across the first and second conductors. This is addressed above and, for example, in U.S. Patent Application Number 2014/0209892.

In an embodiment, the sidewalls 221, 224 are included in a memory 207, such as RRAM (e.g., CBRAM) or a MTJ.

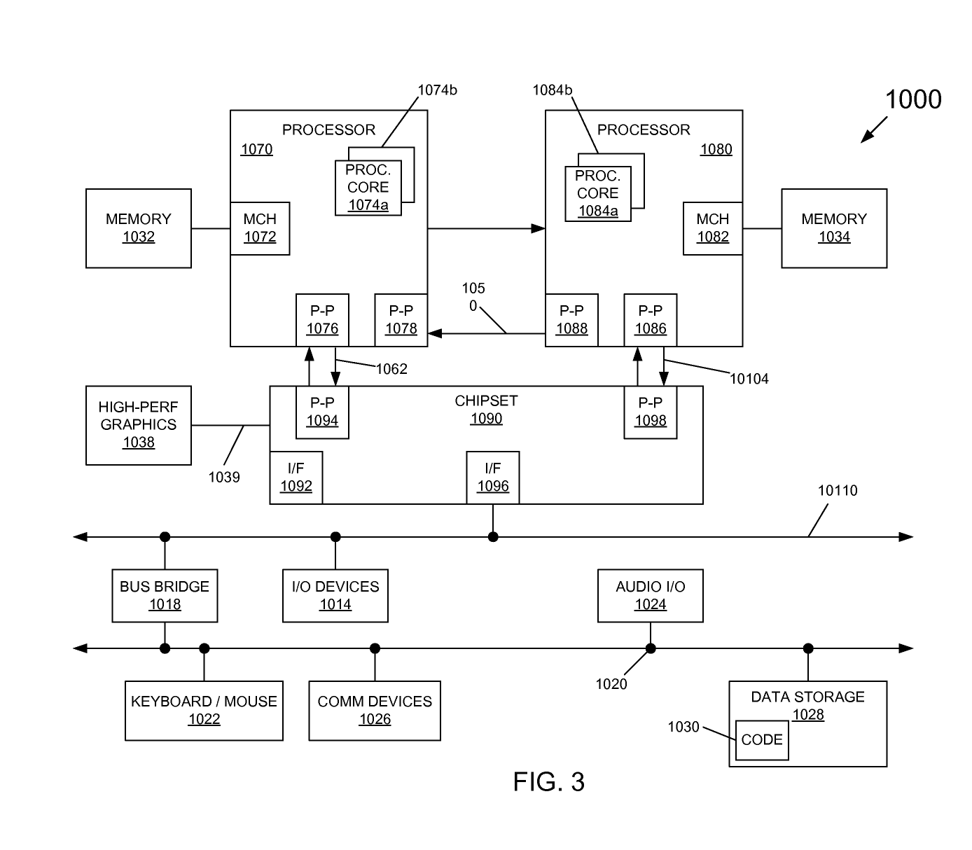

In an embodiment, a system, such as the system of FIG. 3, includes a processor and a memory array including cells, such as cell 214. The processor may couple to an antenna and the like. The system may be in a SoC which includes a metal layer extending from a logic area of the chip (including, for example, a processor) to a memory area of the chip (including cell 214). The metal layer may include WL 201 or BL 213 as well as interconnects (e.g., traces) in the logic area. Thus, a memory array including cells like cell 214 may be integrated with logic to form an embedded memory. Such an embodiment may integrate damascene Cu logic and cells such as cell 214. For example, line 201 and/or line 213 may extend from the array all the way into a logic portion of a SoC where it may then couple (directly or indirectly) with logic components, such as Cu interconnects, traces, and pads that couple to portions of controllers, processors, and the like.

FIG. 3 includes a system that may include any of the above described embodiments. FIG. 3 includes a block diagram of a system embodiment 1000 in accordance with an embodiment of the present invention. System 1000 may include hundreds or thousands of the above described memory cells/stacks (cell 214 of FIG. 2C) and be critical to memory functions in system 1000. System 1000 may be included in, for example, a mobile computing node such as a cellular phone, smartphone, tablet, Ultrabook®, notebook, laptop, personal digital assistant, and mobile processor based platform. The real estate savings of such memory cells accumulates when the memory cells are deployed in mass.

Shown is a multiprocessor system 1000 that includes a first processing element 1070 and a second processing element 1080. While two processing elements 1070 and 1080 are shown, it is to be understood that an embodiment of system 1000 may also include only one such processing element. System 1000 is illustrated as a point-to-point interconnect system, wherein the first processing element 1070 and second processing element 1080 are coupled via a point-to-point interconnect 1050. It should be understood that any or all of the interconnects illustrated may be implemented as a multi-drop bus rather than point-to-point interconnect. As shown, each of processing elements 1070 and 1080 may be multicore processors, including first and second processor cores (i.e., processor cores 1074a and 1074b and processor cores 1084a and 1084b). Such cores 1074, 1074b, 1084a, 1084b may be configured to execute instruction code.

Each processing element 1070, 1080 may include at least one shared cache or memory unit which may include memory stacks/cells described herein. The shared cache may store data (e.g., instructions) that are utilized by one or more components of the processor, such as the cores 1074a , 1074b and 1084a, 1084b, respectively. For example, the shared cache may locally cache data stored in a memory 1032, 1034 for faster access by components of the processor. In one or more embodiments, the shared cache may include one or more mid-level caches, such as level 2 (L2), level 3 (L3), level 4 (L4), or other levels of cache, a last level cache (LLC), and/or combinations thereof.

While shown with only two processing elements 1070, 1080, it is to be understood that the scope of the present invention is not so limited. In other embodiments, one or more additional processing elements may be present in a given processor. Alternatively, one or more of processing elements 1070, 1080 may be an element other than a processor, such as an accelerator or a field programmable gate array. For example, additional processing element(s) may include additional processors(s) that are the same as a first processor 1070, additional processor(s) that are heterogeneous or asymmetric to first processor 1070, accelerators (such as, e.g., graphics accelerators or digital signal processing (DSP) units), field programmable gate arrays, or any other processing element. There can be a variety of differences between the processing elements 1070, 1080 in terms of a spectrum of metrics of merit including architectural, microarchitectural, thermal, power consumption characteristics, and the like. These differences may effectively manifest themselves as asymmetry and heterogeneity amongst the processing elements 1070, 1080. For at least one embodiment, the various processing elements 1070, 1080 may reside in the same die package.

First processing element 1070 may further include memory controller logic (MC) 1072 and point-to-point (P-P) interfaces 1076 and 1078. Similarly, second processing element 1080 may include a MC 1082 and P-P interfaces 1086 and 1088. MC's 1072 and 1082 couple the processors to respective memories, namely a memory 1032 and a memory 1034, which may be portions of main memory locally attached to the respective processors. Memory 1032, 1024 may include memory stacks described herein. While MC logic 1072 and 1082 is illustrated as integrated into the processing elements 1070, 1080, for alternative embodiments the MC logic may be discreet logic outside the processing elements 1070, 1080 rather than integrated therein.

First processing element 1070 and second processing element 1080 may be coupled to an I/O subsystem 1090 via P-P interfaces 1076, 1086 via P-P interconnects 1062, 10104, respectively. As shown, I/O subsystem 1090 includes P-P interfaces 1094 and 1098. Furthermore, I/O subsystem 1090 includes an interface 1092 to couple I/O subsystem 1090 with a high performance graphics engine 1038. In one embodiment, a bus may be used to couple graphics engine 1038 to I/O subsystem 1090. Alternately, a point-to-point interconnect 1039 may couple these components.

In turn, I/O subsystem 1090 may be coupled to a first bus 10110 via an interface 1096. In one embodiment, first bus 10110 may be a Peripheral Component Interconnect (PCI) bus, or a bus such as a PCI Express bus or another third generation I/O interconnect bus, although the scope of the present invention is not so limited.

As shown, various I/O devices 1014, 1024 may be coupled to first bus 10110, along with a bus bridge 1018 which may couple first bus 10110 to a second bus 1020. In one embodiment, second bus 1020 may be a low pin count (LPC) bus. Various devices may be coupled to second bus 1020 including, for example, a keyboard/mouse 1022, communication device(s) 1026 (which may in turn be in communication with a computer network), and a data storage unit 1028 such as a disk drive or other mass storage device (which may include the memory cells described herein) which may include code 1030, in one embodiment. The code 1030 may include instructions for performing embodiments of one or more of the methods described above. Further, an audio I/O 1024 may be coupled to second bus 1020.

Note that other embodiments are contemplated. For example, instead of the point-to-point architecture shown, a system may implement a multi-drop bus or another such communication topology. Also, the elements of FIG. 3 may alternatively be partitioned using more or fewer integrated chips than shown in the FIG. 3. For example, a field programmable gate array may share a single wafer with a processor element and memory including memory cells described herein.

The following examples pertain to further embodiments.

Example 1 includes a method comprising: forming a switch stack plane and a memory stack plane both on a first metal layer; locating a first mask over the memory stack plane and, based on the first mask, removing portions of the switch stack plane, the memory stack plane, and the first metal layer to form a switch stack bar and a memory stack bar over a word line formed from the first metal layer, wherein first switch stack sidewalls of the switch stack bar and first memory stack sidewalls of the memory stack bar are vertically aligned with word line sidewalls of the word line; forming a second metal layer on the word line; and locating a second mask over the word line and, based on the second mask, removing portions of the switch stack bar, the memory stack bar, and the second metal layer to form a memory cell including portions of the switch stack bar and the memory stack bar below a bit line formed from the second metal layer, wherein second switch stack sidewalls of the remaining switch stack bar portion and second memory stack sidewalls of the remaining memory stack bar portion are vertically aligned with bit line sidewalls of the bit line.

In example 2 the subject matter of the Example 1 can optionally include wherein one of the first switch stack sidewalls is substantially orthogonal to one of the second switch stack sidewalls.

In example 3 the subject matter of the Examples 1-2 can optionally include wherein the first switch stack sidewalls and the first memory stack sidewalls are self-aligned to the word line.

In example 4 the subject matter of the Examples 1-3 can optionally include wherein the second switch stack sidewalls and the second memory stack sidewalls are self-aligned to the bit line.

In example 5 the subject matter of the Examples 1-4 can optionally include wherein the switch stack plane includes a thin film switching element with an insulator below an upper electrode and above a lower electrode.

In example 6 the subject matter of the Examples 1-5 can optionally include wherein the insulator includes at least one of vanadium oxide, manganese oxide, titanium oxide, iron oxide, niobium oxide, tantalum oxide, chromium sulphide, iron sulphide, and a compound having the chemical formula R(1−x)AxBO3, where R is a rare-earth atom, A is a bivalent atom, and B may be selected from manganese, nickel, cobalt, titanium, or vanadium.

In example 7 the subject matter of the Examples 1-6 can optionally include wherein the memory cell includes a magnetic tunnel junction (MTJ) that includes the first and second memory stack sidewalls.

In example 8 the subject matter of the Examples 1-7 can optionally include wherein the memory cell includes a resistive random access memory (RRAM) that includes the first and second memory stack sidewalls.

In example 9 the subject matter of the Examples 1-8 can optionally include wherein the one of the first switch stack sidewalls is substantially parallel and opposite another of the first switch stack sidewalls.

In example 10 the subject matter of the Examples 1-9 can optionally include including the memory cell into a memory array that is embedded in a system on a chip (SoC).

Example 11 includes a memory array comprising: a memory cell including a switch stack in series with a memory stack; a bit line above the memory cell and a word line below the memory cell; wherein (a) first switch stack sidewalls of the switch stack are vertically aligned with bit line sidewalls of the bit line and second switch stack sidewalls of the switch stack are vertically aligned with word line sidewalls of the word line; (b) first memory stack sidewalls of the memory stack are vertically aligned with the bit line sidewalls and second memory stack sidewalls of the memory stack are vertically aligned with the word line sidewalls.

In example 12 the subject matter of the Example 11 can optionally include wherein (a) one of the first switch stack sidewalls is substantially orthogonal to one of the second switch stack sidewalls, and (b) the one of the first switch stack sidewalls is substantially parallel and opposite another of the first switch stack sidewalls.

In example 13 the subject matter of the Examples 11-12 can optionally include wherein the first switch stack sidewalls and the first memory stack sidewalls are self-aligned to the word line.

In example 14 the subject matter of the Examples 11-13 can optionally include wherein the second switch stack sidewalls and the second memory stack sidewalls are self-aligned to the bit line.

In example 15 the subject matter of the Examples 11-14 can optionally include wherein the switch stack plane includes an insulator below an upper electrode and above a lower electrode.

In example 16 the subject matter of the Examples 11-15 can optionally include wherein the insulator includes at least one of vanadium oxide, manganese oxide, titanium oxide, iron oxide, niobium oxide, tantalum oxide, chromium sulphide, iron sulphide, and a compound having the chemical formula R(1−x)AxBO3, where R is a rare-earth atom, A is a bivalent atom, and B may be selected from manganese, nickel, cobalt, titanium, or vanadium.

In example 17 the subject matter of the Examples 11-16 can optionally include wherein the first and second switch stack sidewalls are included in a selector element having a threshold voltage VTH, an ON-state voltage, and a snapback voltage VSnapback, such that the selector element transitions from an OFF-state to an ON-state when a voltage potential across the selector element exceeds VTH, and the selector element snaps back to a hold voltage VH while maintaining the ON-State; wherein without the snapback voltage VSnapback, the ON-state voltage would exceed a maximum voltage potential that can be applied across the first and second conductors.

In example 18 the subject matter of the Examples 11-17 can optionally include wherein the memory cell includes a resistive random access memory (RRAM) that includes the first and second memory stack sidewalls.

In example 19 the subject matter of the Examples 11-18 can optionally include wherein the memory cell includes a magnetic tunnel junction (MTJ) that includes the first and second memory stack sidewalls.

In example 20 the subject matter of the Examples 11-19 can optionally include a system comprising: a processor; a memory array, coupled to the processor, according to any one of examples 11 to 19; and a communication module, coupled to the processor, to communicate with a computing node external to the system.

Another example includes the subject matter of the Examples 11-19 can optionally include a system on a chip (SoC) comprising a logic portion coupled to a memory array according to any one of examples 11 to 19.

Example 21 includes an apparatus comprising: at least one processor; and at least memory array, coupled to the at least one processor, comprising: a memory cell including a switch stack in series with a memory stack; and a bit line above the memory cell and a word line below the memory cell; wherein (a) first switch stack sidewalls of the switch stack are vertically aligned with bit line sidewalls of the bit line and second switch stack sidewalls of the switch stack are vertically aligned with word line sidewalls of the word line; (b) first memory stack sidewalls of the memory stack are vertically aligned with the bit line sidewalls and second memory stack sidewalls of the memory stack are vertically aligned with the word line sidewalls.

In example 22 the subject matter of the Example 21 can optionally include wherein the switch stack includes an insulator below an upper electrode and above a lower electrode.

In example 23 the subject matter of the Examples 21-22 can optionally include wherein the first and second switch stack sidewalls are included in a selector element having a threshold voltage V_{TH}, an ON-state voltage, and a snapback voltage V_{Snapback}, such that the selector element transitions from an OFF-state to an ON-state when a voltage potential across the selector element exceeds V_{TH}, and the selector element snaps back to a hold voltage V_{H} while maintaining the ON-State; wherein without the snapback voltage V_{Snapback}, the ON-state voltage would exceed a maximum voltage potential that can be applied across the first and second conductors.

The foregoing description of the embodiments of the invention has been presented for the purposes of illustration and description. It is not intended to be exhaustive or to limit the invention to the precise forms disclosed. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. A method comprising:
forming a switch stack plane and a memory stack plane both on a first metal layer;
locating a first mask over the memory stack plane and, based on the first mask, removing portions of the switch stack plane, the memory stack plane, and the first metal layer to form a switch stack bar and a memory stack bar over a word line formed from the first metal layer, wherein first switch stack sidewalls of the switch stack bar and first memory stack sidewalls of the memory stack bar are vertically aligned with word line sidewalls of the word line;
forming a second metal layer on the word line; and
locating a second mask over the word line and, based on the second mask, removing portions of the switch stack bar, the memory stack bar, and the second metal layer to form a memory cell including portions of the switch stack bar and the memory stack bar below a bit line formed from the second metal layer, wherein second switch stack sidewalls of the remaining switch stack bar portion and second memory stack sidewalls of the remaining memory stack bar portion are vertically aligned with bit line sidewalls of the bit line.

2. The method of claim 1, wherein one of the first switch stack sidewalls is substantially orthogonal to one of the second switch stack sidewalls.

3. The method of claim 2, wherein the first switch stack sidewalls and the first memory stack sidewalls are self-aligned to the word line.

4. The method of claim 3, wherein the second switch stack sidewalls and the second memory stack sidewalls are self-aligned to the bit line.

5. The method of claim 2, wherein the switch stack plane includes a thin film switching element with an insulator below an upper electrode and above a lower electrode.

6. The method of claim 5, wherein the insulator includes at least one of vanadium oxide, manganese oxide, titanium oxide, iron oxide, niobium oxide, tantalum oxide, chromium sulphide, iron sulphide, and a compound having the chemical formula R₍₁₋ₓ₎AₓBO₃, where R is a rare-earth atom, A is a bivalent atom, and B may be selected from the group comprising manganese, nickel, cobalt, titanium, or vanadium.

7. The method of claim 5, wherein the memory cell includes a magnetic tunnel junction (MTJ) that includes the first and second memory stack sidewalls.

8. The method of claim 5, wherein the memory cell includes a resistive random access memory (RRAM) that includes the first and second memory stack sidewalls.

9. The method of claim 2, wherein the one of the first switch stack sidewalls is substantially parallel and opposite another of the first switch stack sidewalls.

10. The method of claim 2, comprising including the memory cell into a memory array that is embedded in a system on a chip (SoC).

11. A memory array comprising:
a memory cell including a switch stack in series with a memory stack; and
a bit line above the memory cell and a word line below the memory cell;
wherein (a) first switch stack sidewalls of the switch stack are vertically aligned with bit line sidewalls of the bit line and second switch stack sidewalls of the switch stack are vertically aligned with word line sidewalls of the word line; (b) first memory stack sidewalls of the memory stack are vertically aligned with the bit line sidewalls and second memory stack sidewalls of the memory stack are vertically aligned with the word line sidewalls.

12. The memory array of claim 11, wherein (a) one of the first switch stack sidewalls is substantially orthogonal to one of the second switch stack sidewalls, and (b) the one of the first switch stack sidewalls is substantially parallel and opposite another of the first switch stack sidewalls.

13. The memory array of claim 12, wherein the first switch stack sidewalls and the first memory stack sidewalls are self-aligned to the bit line.

14. The memory array of claim 13, wherein the second switch stack sidewalls and the second memory stack sidewalls are self-aligned to the word line.

15. The memory array of claim 12, wherein the switch stack includes an insulator below an upper electrode and above a lower electrode.

16. The memory array of claim 15, wherein the insulator includes at least one of vanadium oxide, manganese oxide, titanium oxide, iron oxide, niobium oxide, tantalum oxide, chromium sulphide, iron sulphide, and a compound having the chemical formula R₍₁₋ₓ₎AₓBO₃, where R is a rare-earth atom, A is a bivalent atom, and B may be selected from the group comprising manganese, nickel, cobalt, titanium, or vanadium.

17. The memory array of claim 15,
wherein the first and second switch stack sidewalls are included in a selector element having a threshold voltage V_{TH}, an ON-state voltage, and a snapback voltage V_{Snapback}, such that the selector element transitions from an OFF-state to an ON-state when a voltage potential across the selector element exceeds V_{TH}, and the selector element snaps back to a hold voltage V_{H} while maintaining the ON-State;
wherein without the snapback voltage V_{Snapback}, the ON-state voltage would exceed a maximum voltage potential that can be applied across the first and second conductors.

18. The memory array of claim 15, wherein the memory cell includes a resistive random access memory (RRAM) that includes the first and second memory stack sidewalls.

19. The memory array of claim 15, wherein the memory cell includes a magnetic tunnel junction (MTJ) that includes the first and second memory stack sidewalls.

20. A system comprising:
a processor;
the memory array, coupled to the processor, according to claim 11; and
a communication module, coupled to the processor, to communicate with a computing node external to the system.

21. A system on a chip (SoC) comprising a logic portion coupled to the memory array according to claim 11.

22. An apparatus comprising:
at least one processor; and
at least memory array, coupled to the at least one processor, comprising:
a memory cell including a switch stack in series with a memory stack; and
a bit line above the memory cell and a word line below the memory cell;
wherein (a) first switch stack sidewalls of the switch stack are vertically aligned with bit line sidewalls of the bit line and second switch stack sidewalls of the switch stack are vertically aligned with word line sidewalls of the word line; (b) first memory stack sidewalls of the memory stack are vertically aligned with the bit line sidewalls and second memory stack sidewalls of the memory stack are vertically aligned with the word line sidewalls.

23. The apparatus of claim 22, wherein the switch stack includes an insulator below an upper electrode and above a lower electrode.

24. The apparatus of claim 23,
wherein the first and second switch stack sidewalls are included in a selector element having a threshold voltage V_{TH}, an ON-state voltage, and a snapback voltage V_{Snapback}, such that the selector element transitions from an OFF-state to an ON-state when a voltage potential across the selector element exceeds V_{TH}, and the selector element snaps back to a hold voltage V_{H} while maintaining the ON-State;
wherein without the snapback voltage V_{Snapback}, the ON-state voltage would exceed a maximum voltage potential that can be applied across the first and second conductors.
